(19) United States
(12) Patent Application Publication
(10) Pub. No.: US 2025/0147121 A1
(43) Pub. Date: May 8, 2025

(54) DIGITAL CURRENT METER AND METHODS OF USE THEREOF FOR LEAKAGE/TOUCH CURRENT AND DEVICE INTEROPERABILITY TESTING

(71) Applicant: UL LLC, Northbrook, IL (US)

(72) Inventor: Hai Jiang, Buffalo Grove, IL (US)

(21) Appl. No.: 18/940,724

(22) Filed: Nov. 7, 2024

Related U.S. Application Data
(60) Provisional application No. 63/596,792, filed on Nov. 7, 2023.

(51) Int. Cl. G01R 31/52; G01R 19/10; G01R 19/25

(52) U.S. Cl. CPC G01R 31/52; G01R 19/10; G01R 19/2513

(57) ABSTRACT

An apparatus configured to measure current includes a probe configured to connect to a device under test and touch probe circuitry connected to the probe. The touch probe circuitry is configured to detect, via the probe, a leakage or touch current of the device under test while the device under test is connected to a power source. The apparatus further includes analog to digital converter circuitry configured to receive the leakage or touch current from the touch probe circuitry. The analog to digital converter further outputs at least one digital value related the leakage or touch current. The apparatus further includes current monitor circuitry configured to detect differential current between power lines connected to the device under test. The analog to digital converter circuitry is further configured to receive the differential current from the current monitor circuitry and output at least one digital value related to the differential current.

### Cross-Reference to Related Application

This application claims the benefit of and priority to U.S. provisional patent application Ser. No. 63/596,792, filed Nov. 7, 2023, the entire contents of which are hereby incorporated by reference in its entirety.

### Field of the Disclosure

The present description relates generally to digital current meters and more particularly to digital current meters for sensing and/or testing leakage or touch current of an electronic or electrical products.

### Summary

In some aspects, the techniques described herein relate to an apparatus configured to measure current including at least one probe configured to connect to a device under test and touch probe circuitry connected to the at least one probe. The touch probe circuitry is configured to detect, via the at least one probe, a leakage or touch current of the device under test while the device under test is connected to a power source. The apparatus further includes analog to digital converter circuitry configured to receive the leakage or touch current from the touch probe circuitry. The analog to digital converter further outputs at least one digital value related the leakage or touch current. The apparatus further includes current monitor circuitry configured to detect differential current between power lines connected to the device under test. The analog to digital converter circuitry is further configured to receive the differential current from the current monitor circuitry and output at least one digital value related to the differential current.

In some aspects, the techniques described herein relate to a method for testing a device under test including connecting at least one probe to a device under test. The at least one probe is electrically connected to touch probe circuitry. The method further includes detecting, via the at least one probe and using the touch probe circuitry, an analog leakage or touch current of the device under test while the device under test is connected to a power source. The method further includes converting, using analog to digital converter circuitry, the analog leakage or touch current of the device under test to at least one digital value representative of the analog leakage or touch current of the device under test. The method further includes displaying, on a user interface, the at least one digital value representative of the analog leakage or touch current of the device under test.

In some aspects, the techniques described herein relate to a method for testing a device under test including connecting a test apparatus to a power source and connecting a device under test to the test apparatus. The method further includes detecting, using current monitoring circuitry of the test apparatus, an analog differential current flowing through power wiring of the test apparatus that electrically connects the power source to the device under test. The method further includes converting, using analog to digital converter circuitry, the analog differential current to at least one digital value representative of the analog differential current. The method further includes displaying, on a user interface, the at least one digital value representative of the analog leakage or touch current of the device under test.

### BRIEF DESCRIPTION OF THE DRAWINGS

FIG. 1 illustrates a diagrammatic view of an example current meter according to embodiments of the present disclosure.

FIG. 2 illustrates a diagrammatic view of example components of an example current meter according to embodiments of the present disclosure.

FIG. 3 illustrates a diagrammatic view of example components of an example current meter including multiple current monitors according to embodiments of the present disclosure.

FIG. 4 illustrates a first example display and user interface of an example current meter according to embodiments of the present disclosure.

FIG. 5 illustrates a second example display and user interface of an example current meter according to embodiments of the present disclosure.

FIG. 6 illustrates a third example display and user interface of an example current meter according to embodiments of the present disclosure.

FIG. 7 illustrates a fourth example display and user interface of an example current meter according to embodiments of the present disclosure.

FIG. 8 illustrates diagrammatic examples of different body networks and frequency networks that may be used in an example current meter according to embodiments of the present disclosure.

FIG. 9 is a flowchart illustrating an exemplary method of performing leakage or touch current testing using an example meter according to embodiments of the present disclosure.

FIG. 10 is a flowchart illustrating an exemplary method of performing interoperability indication unit testing using an example meter according to embodiments of the present disclosure.

FIG. 11 is a diagrammatic view of an example embodiment of a user computing environment according to embodiments of the present disclosure.

### DETAILED DESCRIPTION

The following description of example methods and apparatus is not intended to limit the scope of the description to the precise form or forms detailed herein. Instead the following description is intended to be illustrative so that others may follow its teachings.

Described herein are embodiments for apparatuses, systems, methods, and computer readable media for digital leakage/touch current meters and methods for using those digital leakage/touch current meters for sensing and/or testing the leakage or touch current of an electronic or electrical products. Electronic or electrical products may be tested to determine whether they are safe for use by humans, including testing for any leakage current of the device when a human may touch the device. The physiological effects of electrical shock may be induced by current flowing out of a device and into a human, and thus current limits may be specified in safety standards to protect the human body from electrical shock hazards. For example, Underwriters Laboratories (UL) 101 for Leakage Current for Utilization Equipment is a standard that may be used to test the current leakage of certain electronic or electrical products.

A current leakage meter may be used to test such devices and determine how much current may leak out of a device when it is touched by a human user. Described herein is an improved meter that may convert analog data to digital data, which provides improved and more accurate readings for current leakage/touch measurements and testing. Such digital meters may have improved signal-to-noise ratios (SNR) that provides for more accurate measurements. The digital meters described herein may further provide for additional filtering, processing, and customization that may not be possible with analog meters that have hard-wired noise filtering and other analog circuit components.

More particularly, a leakage (or touch) current test, such as in accordance with UL 101 as well as other UL and International Electrotechnical Commission (IEC) tests, is a horizontal compliance test to ensure electrical shock safety for many end-product standards including but not limited to, household/commercial appliances, residential/commercial lighting, information technology Equipment etc. Analog meters, such as one made by Simpson (e.g., the Simpson Model 228 Current Leakage Tester), was previously used widely for such tests. Other hybrid meters, such as the Hioki ST5540, with a digital display available are on the market, but the human body network and frequency network inside the meter are still analog components hardwired into the circuitry of the meter and therefore are not user-programmable.

As electrical product technology evolves, leakage current signals have been moving away from pure sinusoidal towards more complex waveforms, such as those involving high-frequency harmonics. These are due to design trends such as use of variable speed drives (VSD) in consumer electronics instead of linear supplies and other various technology changes. Currently many standards use root-mean-square (RMS) values as the measurement criterion for evaluating leakage/shock hazard, which relies on an average value to calculate signal magnitude and is most appropriate for pure sinusoidal signals. Perception and reaction touch current perceived by humans for complex waveforms may not be adequately interpreted using RMS values. Instead, an advantageous capability of the meters described herein includes the measurement of peak current values may more accurately measure and be used to evaluate shock effects. Some IEC standards have switched from RMS measurement to requiring peak value measurements. However, additional measurements beyond peaks or RMS may also be taken in various embodiments. Other values or measurements that may be of use are currently under investigation, and the embodiments described herein provide the flexibility to adjust the meters described herein to interpret data in different ways as the knowledge base of human perception and the standards evolve. An advantageous capability of this meter described herein includes the capability of measuring either RMS, peak, or quasi-peak current values to evaluate shock effects, as well as the capability to reprogram the meters to measure new, not-yet-determined types of measurements.

The Simpson Model 228 Current Leakage Tester is typically used by testing laboratories and manufacturers to characterize leakage current. This unit is designed to adjust RMS output based on frequency and body impedance, displaying the equivalent shock potential on its analog display. However, the existing Simpson meter is unable to capture peak data, even for simple waveforms. Peak detection in the lab is currently achievable with known equipment but requires the use of oscilloscopes as well as some subjectivity in selection of sample rate and other test parameters, leading to inconsistency in characterizing peak values for a particular waveform. Such a process may not be conducive for certification testing, where simplicity and consistency are desired in test equipment so that data acquisition are tightly controlled and standardized across multiple labs.

The meters described herein include a new all-in-one digital meter integrated with data acquisition and digital program and signal processing modules as shown and described herein. Example meters described herein may include a first feature of an analog-to-digital converter (ADC) as the front-end, acquiring voltage and/or current data (e.g., voltage changes across a known body impedance model) from a device under test (DUT) or equipment under test (EUT). The digital voltage data may be processed by a controller, processor, or microprocessor executing non-transitory computer readable instructions stored on a memory. The digital meters described herein advantageously use digital processing technology after the voltage data is converted by an analog-to-digital converter. For example, instead of using fixed analog circuits and components, all electrical functions and calculations may be accomplished with smaller and lighter integrated circuits and/or software programming in a controller/processor/microprocessor, which allows for reconfiguring and reprogramming the body network and/or frequency network for different standards and/or as desired by a user. For example, the network used by medical standards may be different from household appliances.

As such, another advantage of various meters described herein is that they are programmable and reconfigurable. This allows for future-proofing of the meters described herein, as the meters may have their software updated so that the body impedance and/or frequency networks may be updated via software updates (e.g., upon relevant standards being changed). For example, leakage current signals measured in the past may have been pure sinusoidal waveforms, whereas more complicated waveforms involving high-frequency harmonics and more may be present in devices today. In addition, various safety standards may use root-mean-square (RMS) and/or peak values as measurement criterion for evaluating leakage/shock hazard. Peak value measurements may provide additional safety margin beyond RMS measurements (e.g., as a more stringent criterion), and peak value measurements may match true human sensation better than measuring RMS in various cases. In addition to RMS and peak value measurements, a third quantity may be measured by the devices described here. That third quantity may be, for example, a quasi-peak that may be advantageously useful in defining shock effect. Since the meters described herein use digital programming, the meters may be reconfigured or reprogrammed to implement any algorithm for the output which may be any of RMS measurements, peak value measurements, a user defined quasi-peak measurement, or any other type of measurement desired.

Another advantage of the meters described herein is their capability of conducting an interoperability indication unit (IIU) test. The interoperability indication unit (IIU) test, such as that as included in the UL 101 standard examines the interoperability of utilization equipment with a ground fault interrupter (GFI) or ground fault circuit interrupter (GFCI) device by measuring differential current on the power lines running to/through the DUT or EUT. The meters described herein therefore have the advantageous capability of conducting both leakage current tests and the IIU test. Both results may be advantageously computed digitally instead of passing through any physical components.

Another advantage of the digital meters described herein is that they can provide higher signal to noise ratio and better accuracy for measurement peak values compared with analog meters that use analog components for body network and frequency network of the meter. For example, a sample rate may be set and/or customized based on standardized upper limits for evaluating peak values (e.g., as the human body becomes ever less sensitive to leakage current as the frequency increases, therefore monitoring peak values may be irrelevant above a certain frequency once the value exceeds other limits such as a 70 mA burn limit, etc.). The limits set may be any limit dictated by a standard or desired by a user. As such, a meter may have a customizable or default maximum sampling frequency, such as one based on a burn, Dalziel, and/or Nyquist sampling limit.

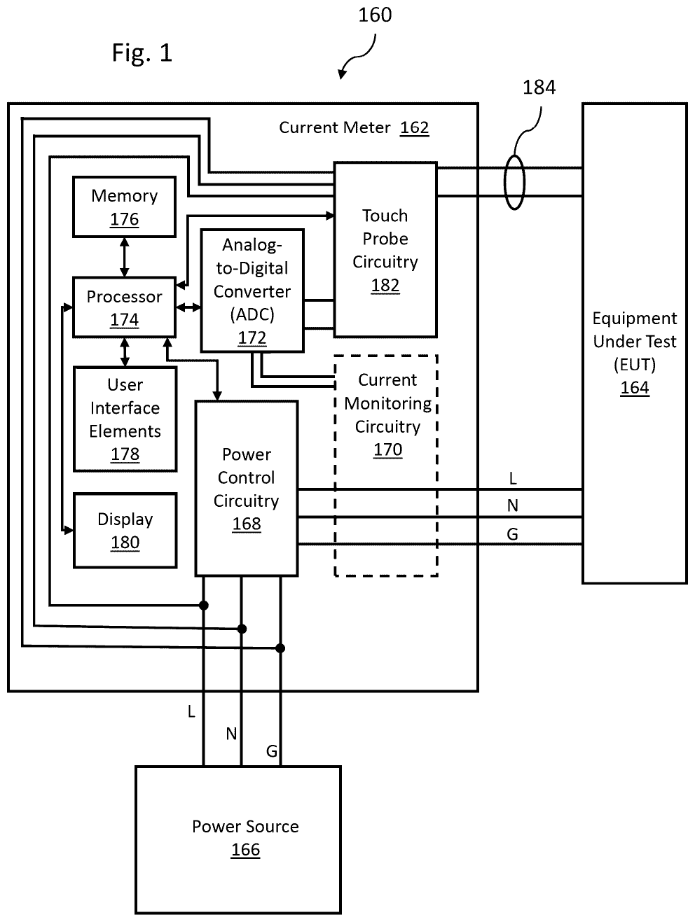

FIG. 1 illustrates a diagrammatic view 160 of an example current meter 162 according to embodiments of the present disclosure. The current meters herein, including the current meter 162, contains general testing capabilities that may be used with or for various end-product standards including switching polarity, open neutral, open ground, etc. The current meter 162 includes an analog-to-digital converter (ADC) 172 (also referred to herein is analog-to-digital (ADC) circuitry) that is connected to probes 184 that may be attached to equipment under test (EUT) 164 (e.g., an electronic or electrical product for testing, which may also be referred to as a device under test (DUT)) via touch probe circuitry 182. The ADC 172 may then receive analog values from the probes 184, convert the analog values to digital data, and output the digital data to a processor 174, which may use default settings and instructions stored on memory 176 or customized settings and instructions on the memory 176 to process the digital data in various ways and output data based on the processing, instructions, etc. for a given test being performed. That output data may be output to a display 180, such as the liquid crystal display (LCD) screen or other type of electronic display. The output data may also be transmitted to another computing device using a wired or wireless transceiver (not shown) of the current meter 162. A power source 166 may further be connected to the current meter and supply power to power control circuitry 168. Although the connections for such power are not shown in FIG. 1, the power source 166 may also be used to supply power to the processor 174, the display 180, the ADC 172, and/or the memory 176.

In various embodiments, the current meter 162 may additionally or alternatively have a power source for the processor 174, the display 180, the ADC 172, and/or the memory 176 built into the current meter 162, such as a battery (not shown). In various embodiments, an alternating current (AC) power source (e.g., from a wall supply) may be separately connected to the current meter 162 separate from the power source 166. The current meter may also include user interface elements 178 configured to receive user inputs and interactions from/with a user. In various embodiments, the display 180 and at least some of the user interface elements 178 may be combined in common hardware, such as a touchscreen configured to display information and receive user inputs. In various embodiments, the user interface elements 178 may also include any of buttons, switches, dials, a keyboard, mouse, trackpad, or any other user interface element compatible with computing or electronic devices. The term user interface may also be further used herein to describe both user interface elements and a display collectively, as a display also provides an interface to a user.

The power control circuitry 168 is removably connectable to the power source 166 (e.g., the current meter may be unplugged or otherwise disconnected from the power source 166). Similarly, the probes 184 may be removably connectable to the EUT 164. For example, in many touch/leakage current tests, leads of the probes 184 may be placed in contact with or on an enclosure or outside surface of the EUT 164 and removed once the test is complete. Similarly, the power lines connecting the power control circuitry and the EUT 164 to supply power to the EUT 164 may also be removably connectable. For example, the current meter 162 may have a receptacle so that the EUT 164 may be plugged into the current meter 162 to receive power from the power source 166 via the power control circuitry 168. The power control circuitry 168 may control the power delivered to the EUT 164, and the current monitoring circuitry may monitor the current or other aspects of that power delivered to the EUT 164. For example, the current monitoring circuitry 170 may include a current monitor such as a transformer to detect differential current between two of the power lines running from the power control circuitry 168 to the EUT 164. Such monitoring may be performed as part of an interoperability indication unit (IIU) test. An output from the current monitoring circuitry 170 (e.g., the differential current measured) may be output to the ADC 172 so that the analog measurement may be converted to a digital value and processed by the processor 174 according to the instructions stored in the memory 176. Data related to that digital value and data related to the processing performed by the processor 174 may then be output to the display 180.

The processor 174 is also connected to the touch probe circuitry 182, the ADC 172, and the power control circuitry 168. In this way, the processor 174 may control aspects of the touch probe circuitry 182, the ADC 172, and the power control circuitry 168. For example, as described herein, the touch probe circuitry 182 and the power control circuitry 168 may have various switches for controlling different tests or aspects of tests that may be performed on the EUT 164. In addition, various aspects of the touch probe circuitry 182, the ADC 172, and the power control circuitry 168 may be reconfigurable or reprogrammable for different tests (e.g., to implement a new body network and/or frequency network for a given test, to apply different test parameters for a given test, etc.). Through the connections to the processor 174, the processor 174 may therefore carry out such instructions stored on the memory and/or received through the user interface elements 178 to reconfigure or reprogram various aspects of the touch probe circuitry 182, the ADC 172, and the power control circuitry 168. In addition, through a wired or wireless transceiver, the instructions on the memory 176 may be updated over time to provide new types of test parameters or other ways to reconfigure or reprogram the touch probe circuitry 182, the ADC 172, and the power control circuitry 168 (e.g., to implement a new body network and/or frequency network for a given test, to apply different test parameters for a given test, etc.).

As such, the touch probe circuitry 182 connected to the probes 184 is configured to detect, via the probes 184, a leakage or touch current of an enclosure of the EUT 164 while the EUT is connected to a power source (e.g., while the EUT 164 is in operation). The ADC 172 is then configured to receive an analog leakage or touch current measurement from the touch probe circuitry 182. The ADC 172 then converts the analog value to a digital value and outputs at least one digital value related the leakage or touch current to the processor 174. The current monitor circuitry 170 is configured to detect differential current between power lines connected to the EUT 164, and the ADC 172 circuitry is further configured to receive the differential current measurement from the current monitor circuitry and output at least one digital value related to the differential current (which may be an analog value output by the current monitoring circuitry 170).

A power wiring connector of the current meter 162 may be removably connectable to the external power source 166 to connect the power source 166 with the power control circuitry 168. The power wiring connector may therefore supply power to the touch probe circuitry and the current monitor circuitry while the power wiring connector of the current meter 162 is connected to the external power source 166.

As described above, the current meter 162 may also have a receptacle for receiving a power wiring connector of the EUT 164. While the current meter 162 is connected to the external power source 166 and the power wiring connector of the EUT 164 is connected to the receptacle of the current meter 162, the current monitor circuitry 170 is configured to detect, for example, a difference in current flowing between a hot line and a neutral line connected to the EUT 164 (e.g., for an EUT using 120 volt (V) power) or a difference in current flowing between a first hot line and a second hot line connected to the EUT 164 (e.g., for an EUT using 240 V power).

The current meter 162 may also include network circuitry (not separately shown in FIG. 1) configured to simulate a body network or frequency network. The network circuitry may be located between and connected to the touch probe circuitry and the ADC 172, or may be considered part of the touch probe circuitry 182. Such network circuitry may be reconfigurable and/or reprogrammable by the processor 174 as described herein to implement different body networks or frequency networks for different tests as desired.

The current monitor circuitry 170 may include at least one transformer.

As described herein, the memory 176 may have stored thereon non-transitory computer-readable instructions that, upon execution by the processor, cause the current meter 162 to perform various functions. For example, the instructions may cause the current meter 162 to display on a user interface including the display 180 at least one value associated with a digital current measurement of the leakage or touch current (e.g., measured by the touch probe circuitry) or the differential current (e.g., measured by the current monitoring circuitry 170). The instructions on the memory may further cause the current meter 162 to display a depiction of a currently selected simulated body network or frequency network. The instructions on the memory may further cause the current meter 162 to display options for switching the touch probe circuitry to connect at least one of the probes 184 to at least one of a hot line, a neutral line, or a ground line of the power connected to the touch probe circuitry 182 from the power source 166. The power control circuitry 168 may also include at least one switch configured to switch a polarity of power supplied to the device under test, so that the instructions on the memory may further cause the current meter 162 to display a user interface element configured to permit user selection of the polarity of power supplied to the device under test. The power control circuitry 168 may also include at least one switch configured to switch to at least one of an open neutral condition or an open ground condition of power supplied to the device under test, so that the instructions on the memory may further cause the current meter 162 to display a user interface element configured to permit user selection of the open neutral condition or the open ground condition of power supplied to the device under test. The instructions on the memory may further cause the current meter 162 to display a user interface element configured to permit user selection of a simulated body network or frequency network.

As described herein, the at least one value associated with a digital current measurement of the leakage or touch current may be at least one of a peak leakage current measurement, a quasi-peak leakage current measurement, or a root-mean-square (RMS) leakage current measurement. The instructions on the memory may further cause the current meter 162 to display at least one of the peak leakage current measurement, the quasi-peak leakage current measurement, the RMS leakage current measurement a voltage of the device under test, a current of the device under test, a power level of the device under test, an energy level of the device under test, or a sample frequency of the device under test.

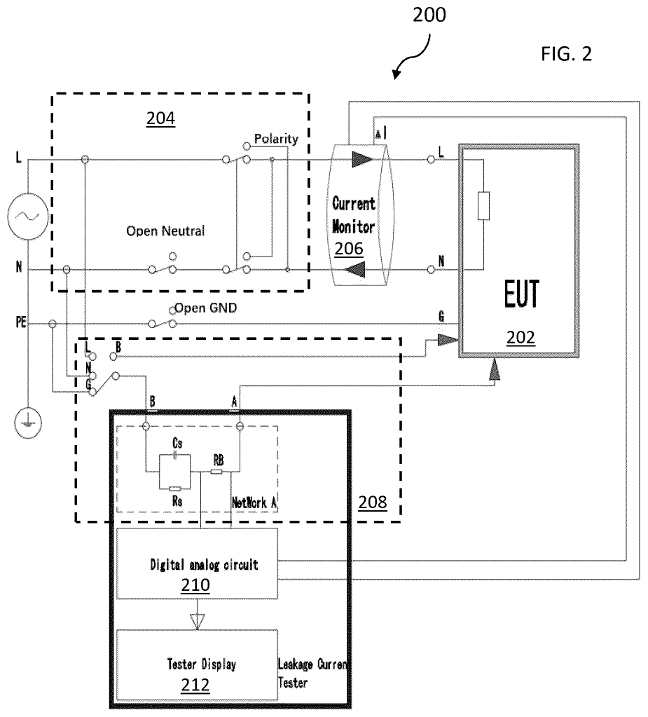

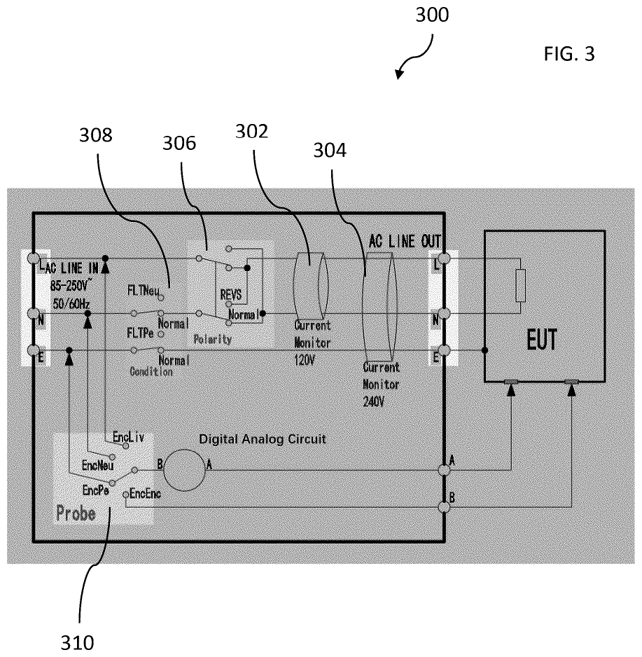

FIG. 2 illustrates a diagrammatic view of example components of an example current meter 200 according to embodiments of the present disclosure. The current meter 200 in FIG. 2 includes an ADC 210 and a display 212. The current meter 200 further includes an example body network A that may be digitally implemented according to instructions stored on a memory and executed by a processor as described herein. The body network A after the front-end input A and B may also composed by analog components. When composed of analog components, the current meter 200 may switch to different analog components that represent different body or frequency networks for a given test as desired, as opposed to implementing those networks digitally. The body network A may, for example, serve as a dummy load impedance network of simulating a human body, so the voltage measured between A and B is the same value across the human body which will be further processed by the digital program inside the digital analog circuit module as shown. As shown, the body network A may be part of touch probe circuitry 208, though in other embodiments may be a separate circuitry between touch probe circuitry and ADC circuitry. A current monitor 206 may include a current transformer integrated for conducting an IIU test where it measures the differential current between hot and neutral wires (e.g., for a single phase 120 V EUT 202. For a 240 V product, a second transformer as shown in FIG. 3 may be used. FIG. 3 illustrates a diagrammatic view of example components of an example current meter 300 including multiple current monitors 302 and 304 according to embodiments of the present disclosure. Although not shown in FIG. 3, the output of both the current monitors 302 and 304 feeds into an analog-to-digital circuit for post digital processing and displaying of results.

The current monitor 300 further shows in more detail the polarity switches 306 and condition switches 308 that may be part of a power control circuitry of a current meter. The current monitor 300 also shows in more detail the probe switches 310 that may be part of a touch probe circuitry of a current meter.

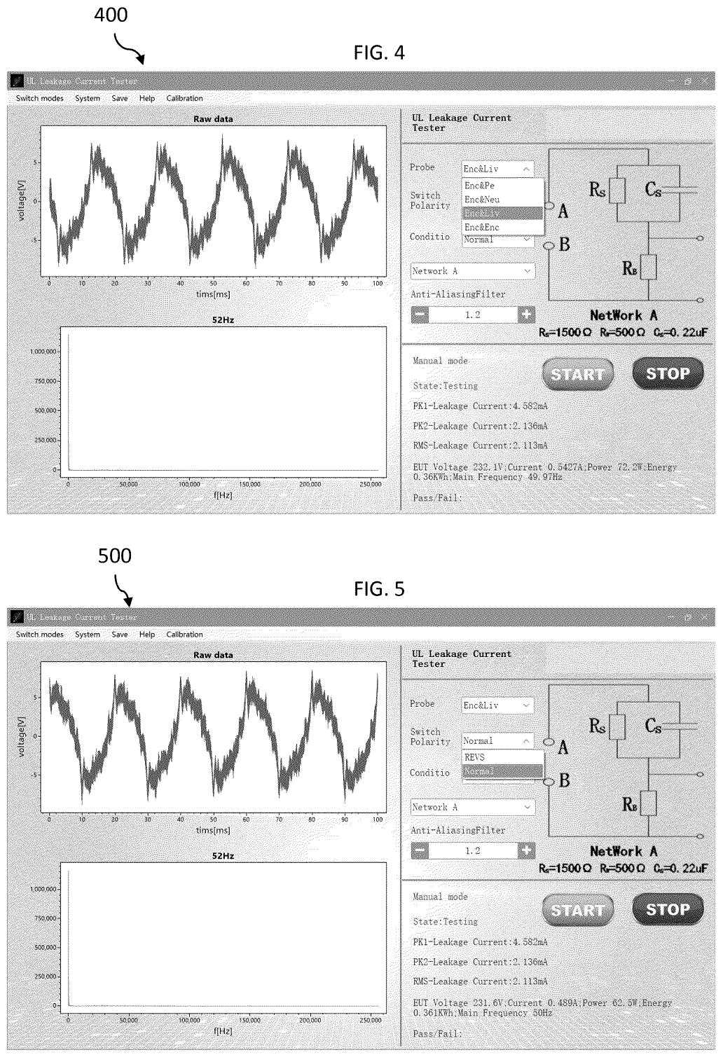

FIG. 4 illustrates a first example display and user interface 400 of an example current meter according to embodiments of the present disclosure. The user interface 400 shows drop down options selectable by a user that cause a processor to control, for example, the probe switches 310 of FIG. 3. Those probe options selectable by a user include options associated with each of four positions of the probe switches 310: (1) Enc&Pe: Leakage Between Enclosure and Ground/Earth; (2) Enc&Neu: Leakage Between EUT Enclosure and Neutral Line; (3) Enc&Liv: Leakage Between EUT Enclosure and Hot Line; and (4) Enc&Enc: Leakage Between EUT Enclosure and EUT Enclosure.

FIG. 5 illustrates a second example display and user interface 500 of an example current meter according to embodiments of the present disclosure. The user interface 500 shows drop down options selectable by a user that cause a processor to control, for example, the polarity switches 306 of the current monitor 300 in FIG. 3. Those options selectable by a user include options associated with each of two positions of the polarity switches 306: (1) normal polarity and (2) REVS: reverse polarity between hot and neutral lines.

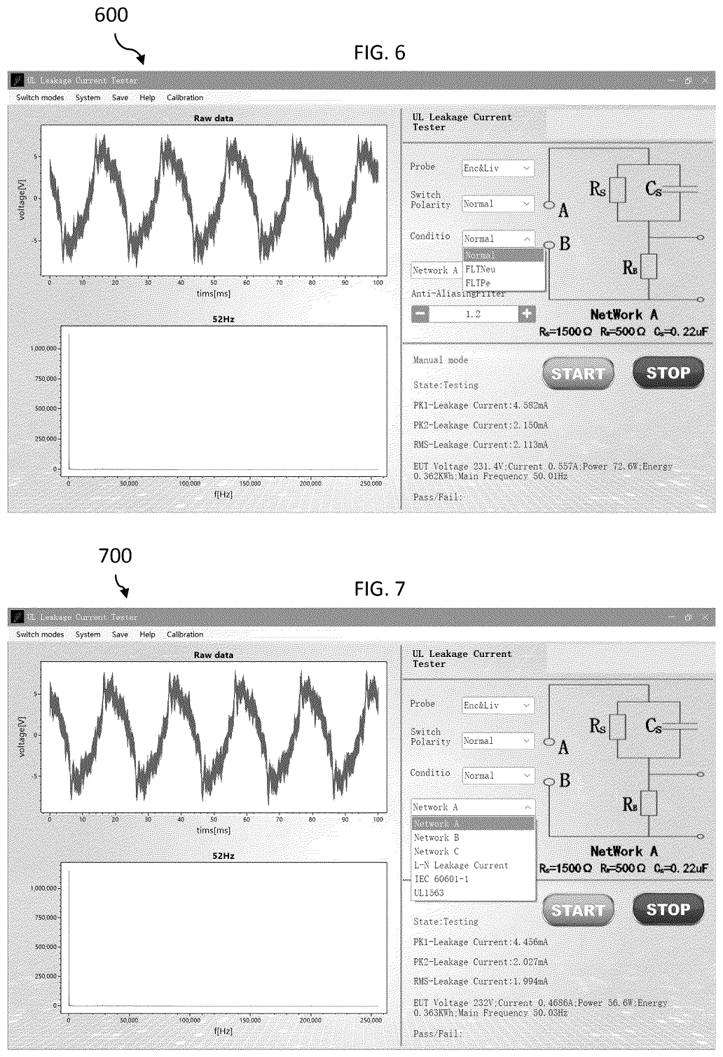

FIG. 6 illustrates a third example display and user interface 600 of an example current meter according to embodiments of the present disclosure. The user interface 600 shows drop down options selectable by a user that cause a processor to control, for example, the condition switches 308 of the current monitor 300 in FIG. 3. Those options selectable by a user include options associated with the condition switches 308: (1) normal (both switches closed); (2) FLTNeu: Open Neutral Switch; and (3) FLTPe: Open Ground/Earth Switch.

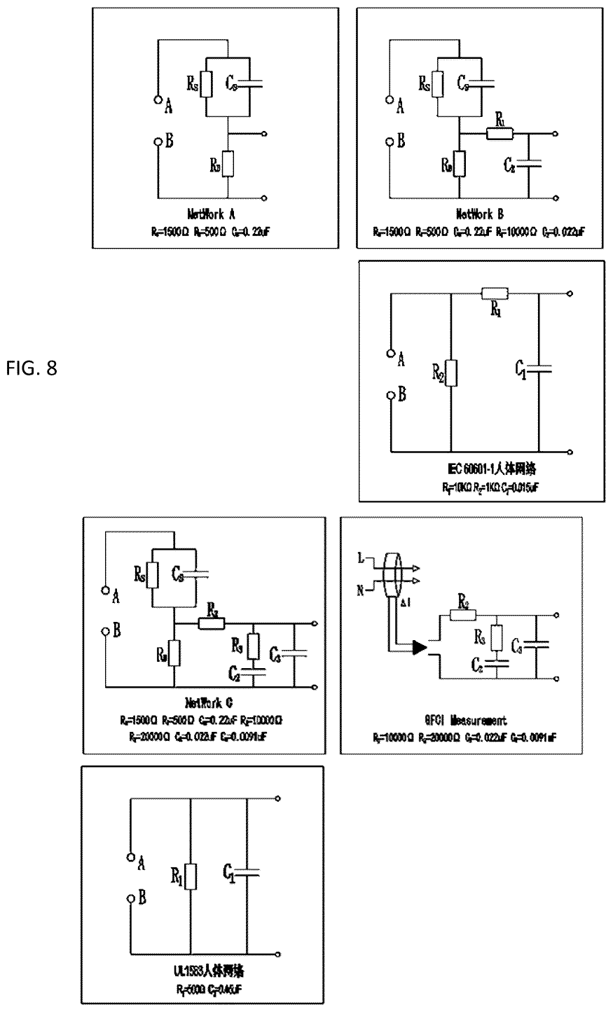

FIG. 7 illustrates a fourth example display and user interface 700 of an example current meter according to embodiments of the present disclosure. The user interface 700 shows drop down options selectable by a user that cause a processor to control, for example, the body or frequency network currently being used. In FIG. 7, a network A is currently selected and being used, and a depiction of the network A is displayed in the top right of the user interface 700. The options selectable by a user in the example of FIG. 7 include options associated with the example options of different body networks and frequency networks shown in FIG. 8: (1) Network A: Burn; (2) Network B: Reaction; (3) Network C: Let-go; (4) L-N Leakage Current: related to an IIU test; (5) IEC 60601-1: Medical test; and (6) UL 1563 test.

FIGS. 4-7 also include start and stop buttons for a user to start or stop testing of a device as well as a state indicator (e.g., testing or not testing/stopped) of the current meter so a user can see whether a test is currently being run or not. FIGS. 4-7 also include a raw data output display and a frequency output display. FIGS. 4-7 also include different leakage current measurement output levels, such as a peak 1 leakage current level, a peak 2 leakage current level, an RMS leakage current level, etc. In this way the display may output different values (peak, quasi-peak, RMS) simultaneously during a test of a device. FIGS. 4-7 may further include outputs showing a present EUT voltage, current, power, energy, and main frequency. A pass/fail indicator may also be included in FIGS. 4-7 so that the current meter can output whether the device under test has passed or failed a given test. In various embodiments, instead of manually selecting from the dropdowns shown in FIGS. 4-7, a user interface may allow a user to select a type of test to perform, and the current meter may cycle through the necessary drop down items for that test and output a test result (e.g., pass/fail, measurements related to different aspects of the test, etc.).

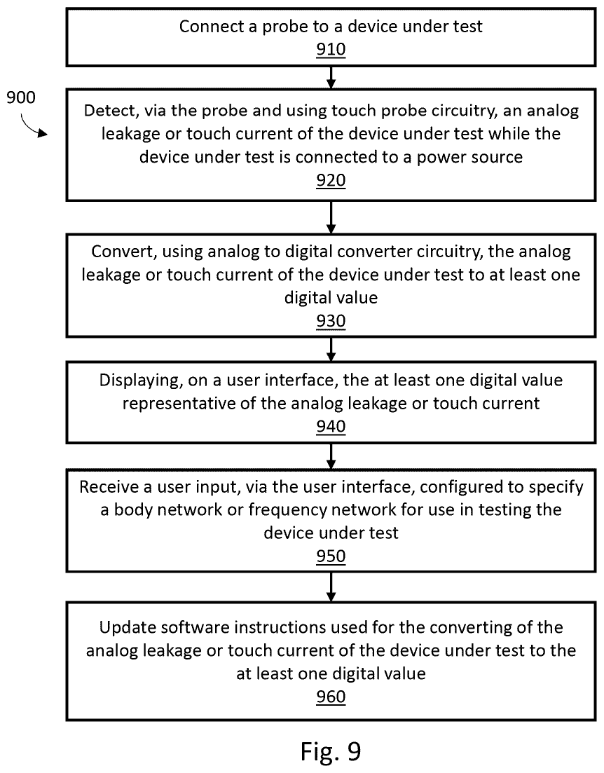

FIG. 9 is a flowchart illustrating an exemplary method 900 of performing leakage or touch current testing using an example meter according to embodiments of the present disclosure. At an operation 910, at least one probe is connected to a device under test The at least one probe is electrically connected to touch probe circuitry. At an operation 920, an analog leakage or touch current of the device under test is detected, via the at least one probe and using the touch probe circuitry, while the device under test is connected to a power source. At an operation 930, the analog leakage or touch current of the device under test is converted, using analog to digital converter circuitry, to at least one digital value representative of the analog leakage or touch current of the device under test. At an operation 940, the at least one digital value representative of the analog leakage or touch current of the device under test is displayed on a user interface. At an operation 950, a user input is received, via the user interface, that specifies a body network or frequency network for use in testing the device under test. At an operation 960, software instructions used for the converting of the analog leakage or touch current of the device under test to the at least one digital value are updated.

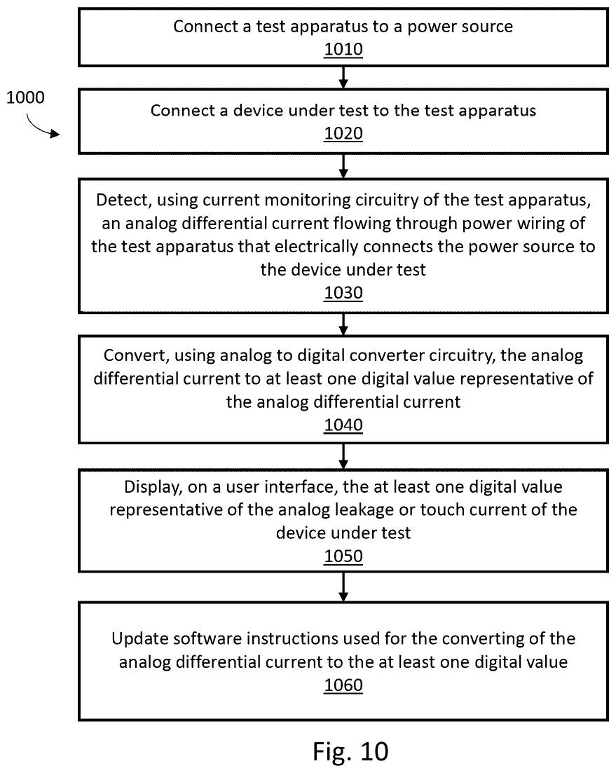

FIG. 10 is a flowchart illustrating an exemplary method 1000 of performing interoperability indication unit testing using an example meter according to embodiments of the present disclosure. At an operation 1010, a test apparatus is connected to a power source. At an operation 1020, a device under test is connected to the test apparatus. At an operation 1030, an analog differential current flowing through power wiring of the test apparatus that electrically connects the power source to the device under test is detected using current monitoring circuitry of the test apparatus. At an operation 1040, the analog differential current is converted, using analog to digital converter circuitry, to at least one digital value representative of the analog differential current. At an operation 1050, the at least one digital value representative of the analog leakage or touch current of the device under test is displayed on a user interface. At an operation 1060 software instructions used for the converting of the analog differential current to the at least one digital value are updated.

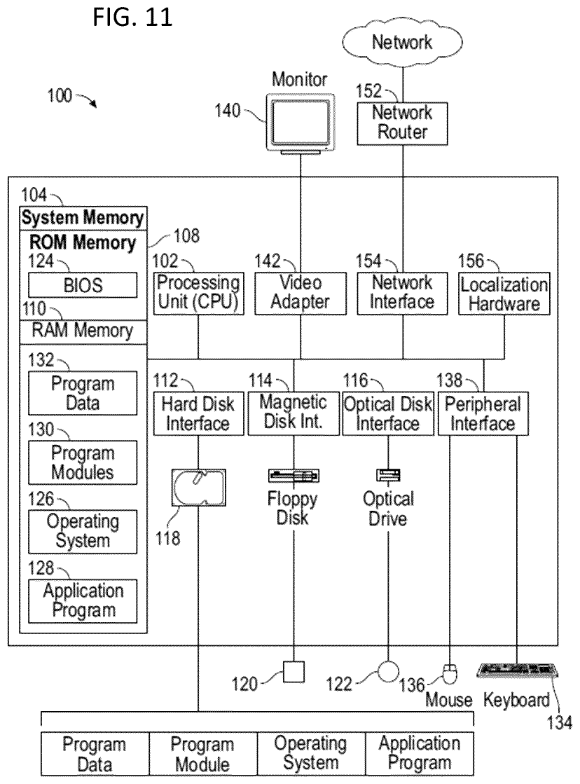

FIG. 11 is a diagrammatic view of an example embodiment of a user computing environment that includes a general-purpose computing system environment 100, such as a desktop computer, laptop, smartphone, tablet, or any other such device having the ability to execute instructions, such as those stored within a non-transient, computer-readable medium. The aspects of the figure below and described herein may be used in accordance with the embodiments herein to communicate with the meters described herein, program the meters described herein, etc. Some or all of aspects of the figure below and described herein may further be used as components of the meters described herein (e.g., the at least one processing unit 102 may be part or all of a processor/controller/microprocessor, the monitor 140 may be a display or user interface, the hard disk 118, magnetic disk, optical drive, or a flash memory may be a memory as described herein, etc.). In addition, the aspects of the figure below may have instructions stored thereon for implementing any of the methods or functions described herein.

Furthermore, while described and illustrated in the context of a single computing system 100, those skilled in the art will also appreciate that the various tasks described hereinafter may be practiced in a distributed environment having multiple computing systems 100 linked via a local or wide-area network in which the executable instructions may be associated with and/or executed by one or more of multiple computing systems 100.

In its most basic configuration, computing system environment 100 typically includes at least one processing unit 102 and at least one memory 104, which may be linked via a bus 106. Depending on the exact configuration and type of computing system environment, memory 104 may be volatile (such as RAM 110), non-volatile (such as ROM 108, flash memory, etc.) or some combination of the two. Computing system environment 100 may have additional features and/or functionality. For example, computing system environment 100 may also include additional storage (removable and/or non-removable) including, but not limited to, magnetic or optical disks, tape drives and/or flash drives. Such additional memory devices may be made accessible to the computing system environment 100 by means of, for example, a hard disk drive interface 112, a magnetic disk drive interface 114, and/or an optical disk drive interface 116. As will be understood, these devices, which would be linked to the system bus 306, respectively, allow for reading from and writing to a hard disk 118, reading from or writing to a removable magnetic disk 120, and/or for reading from or writing to a removable optical disk 122, such as a CD/DVD ROM or other optical media. The drive interfaces and their associated computer-readable media allow for the nonvolatile storage of computer readable instructions, data structures, program modules and other data for the computing system environment 100. Those skilled in the art will further appreciate that other types of computer readable media that can store data may be used for this same purpose. Examples of such media devices include, but are not limited to, magnetic cassettes, flash memory cards, digital videodisks, Bernoulli cartridges, random access memories, nano-drives, memory sticks, other read/write and/or read-only memories and/or any other method or technology for storage of information such as computer readable instructions, data structures, program modules or other data. Any such computer storage media may be part of computing system environment 100.

A number of program modules may be stored in one or more of the memory/media devices. For example, a basic input/output system (BIOS) 124, containing the basic routines that help to transfer information between elements within the computing system environment 100, such as during start-up, may be stored in ROM 108. Similarly, RAM 110, hard drive 118, and/or peripheral memory devices may be used to store computer executable instructions comprising an operating system 126, one or more applications programs 128 (which may include the functionality disclosed herein, for example), other program modules 130, and/or program data 122. Still further, computer-executable instructions may be downloaded to the computing environment 100 as needed, for example, via a network connection.

An end-user may enter commands and information into the computing system environment 100 through input devices such as a keyboard 134 and/or a pointing device 136. While not illustrated, other input devices may include a microphone, a joystick, a game pad, a scanner, etc. These and other input devices would typically be connected to the processing unit 102 by means of a peripheral interface 138 which, in turn, would be coupled to bus 106. Input devices may be directly or indirectly connected to processor 102 via interfaces such as, for example, a parallel port, game port, firewire, or a universal serial bus (USB). To view information from the computing system environment 100, a monitor 140 or other type of display device may also be connected to bus 106 via an interface, such as via video adapter 132. In addition to the monitor 140, the computing system environment 100 may also include other peripheral output devices, not shown, such as speakers and printers.

The computing system environment 100 may also utilize logical connections to one or more computing system environments. Communications between the computing system environment 100 and the remote computing system environment may be exchanged via a further processing device, such a network router 152, that is responsible for network routing. Communications with the network router 152 may be performed via a network interface component 154. Thus, within such a networked environment, e.g., the Internet, World Wide Web, LAN, or other like type of wired or wireless network, it will be appreciated that program modules depicted relative to the computing system environment 100, or portions thereof, may be stored in the memory storage device(s) of the computing system environment 100.

The computing system environment 100 may also include localization hardware 186 for determining a location of the computing system environment 100. In embodiments, the localization hardware 156 may include, for example only, a GPS antenna, an RFID chip or reader, a WiFi antenna, or other computing hardware that may be used to capture or transmit signals that may be used to determine the location of the computing system environment 100.

While this disclosure has described certain embodiments, it will be understood that the claims are not intended to be limited to these embodiments except as explicitly recited in the claims. On the contrary, the instant disclosure is intended to cover alternatives, modifications and equivalents, which may be included within the spirit and scope of the disclosure. Furthermore, in the detailed description of the present disclosure, numerous specific details are set forth in order to provide a thorough understanding of the disclosed embodiments. However, it will be obvious to one of ordinary skill in the art that systems and methods consistent with this disclosure may be practiced without these specific details. In other instances, well known methods, procedures, components, and circuits have not been described in detail as not to unnecessarily obscure various aspects of the present disclosure.

Some portions of the detailed descriptions of this disclosure have been presented in terms of procedures, logic blocks, processing, and other symbolic representations of operations on data bits within a computer or digital system memory. These descriptions and representations are the means used by those skilled in the data processing arts to most effectively convey the substance of their work to others skilled in the art. A procedure, logic block, process, etc., is herein, and generally, conceived to be a self-consistent sequence of steps or instructions leading to a desired result. The steps are those requiring physical manipulations of physical quantities. Usually, though not necessarily, these physical manipulations take the form of electrical or magnetic data capable of being stored, transferred, combined, compared, and otherwise manipulated in a computer system or similar electronic computing device. For reasons of convenience, and with reference to common usage, such data is referred to as bits, values, elements, symbols, characters, terms, numbers, or the like, with reference to various presently disclosed embodiments.

It should be borne in mind, however, that these terms are to be interpreted as referencing physical manipulations and quantities and are merely convenient labels that should be interpreted further in view of terms commonly used in the art. Unless specifically stated otherwise, as apparent from the discussion herein, it is understood that throughout discussions of the present embodiment, discussions utilizing terms such as “determining” or “outputting” or “transmitting” or “recording” or “locating” or “storing” or “displaying” or “receiving” or “recognizing” or “utilizing” or “generating” or “providing” or “accessing” or “checking” or “notifying” or “delivering” or the like, refer to the action and processes of a computer system, or similar electronic computing device, that manipulates and transforms data. The data is represented as physical (electronic) quantities within the computer system's registers and memories and is transformed into other data similarly represented as physical quantities within the computer system memories or registers, or other such information storage, transmission, or display devices as described herein or otherwise understood to one of ordinary skill in the art.

What is claimed is:

1. An apparatus configured to measure current comprising:
at least one probe configured to connect to a device under test;
touch probe circuitry connected to the at least one probe, wherein the touch probe circuitry is configured to detect, via the at least one probe, a leakage or touch current of the device under test while the device under test is connected to a power source; and
analog to digital converter circuitry configured to receive the leakage or touch current from the touch probe circuitry, wherein the analog to digital converter further outputs at least one digital value related the leakage or touch current.

2. The apparatus of claim 1, further comprising current monitor circuitry configured to detect differential current between power lines connected to the device under test, wherein the analog to digital converter circuitry is further configured to receive the differential current from the current monitor circuitry and output at least one digital value related to the differential current.

3. The apparatus of claim 1, further comprising a power wiring connector of the apparatus connectable to an external power source, wherein the power wiring connector of the apparatus is configured to supply power to at least one switch of the touch probe circuitry while the power wiring connector of the apparatus is connected to the external power source.

4. The apparatus of claim 1, further comprising network circuitry configured to digitally simulate a body network or frequency network, wherein the network circuitry is between and connected to the touch probe circuitry and the analog to digital converter circuitry.

5. The apparatus of claim 1, further comprising a user interface, a processor, and a memory having stored thereon non-transitory computer-readable instructions that, upon execution by the processor, cause the apparatus to display on the user interface at least one value associated with a digital current measurement of the leakage or touch current.

6. The apparatus of claim 5, wherein the instructions further cause the apparatus to display on the user interface a depiction of a currently selected digitally simulated body network or frequency network.

7. The apparatus of claim 5, wherein the touch probe circuitry comprises at least one switch configured to connect the touch probe circuitry to at least one of a hot line, a neutral line, a ground line; wherein the instructions further cause the apparatus to display on the user interface a user interface element configured to permit user selection of the touch probe circuitry connection to the at least one of a hot line, a neutral line, a ground line.

8. The apparatus of claim 5, wherein the instructions further cause the apparatus to display a user interface element configured to permit user selection of a digitally simulated body network or frequency network.

9. The apparatus of claim 5, wherein the at least one value associated with a digital current measurement of the leakage or touch current or the differential current comprises at least one of a peak leakage current measurement, a quasi-peak leakage current measurement, or a root-mean-square (RMS) leakage current measurement.

10. The apparatus of claim 5, wherein the instructions further cause the apparatus to display at least one of a voltage of the device under test, a current of the device under test, a power level of the device under test, an energy level of the device under test, or a sample frequency of the device under test.

11. An apparatus configured to measure current comprising:
current monitor circuitry configured to detect differential current between power lines connected to a device under test; and
analog to digital converter circuitry configured to receive the differential current from the current monitor circuitry and output at least one digital value related to the differential current.

12. The apparatus of claim 11, further comprising:
at least one probe configured to connect to the device under test; and
touch probe circuitry connected to the at least one probe, wherein the touch probe circuitry is configured to detect, via the at least one probe, a leakage or touch current of the device under test while the device under test is connected to a power source,
wherein the analog to digital converter circuitry is further configured to receive the leakage or touch current from the touch probe circuitry, and
wherein the analog to digital converter further outputs at least one digital value related the leakage or touch current.

13. The apparatus of claim 11, further comprising a receptacle for receiving a power wiring connector of the device under test.

14. The apparatus of claim 13, wherein while the power wiring connector of the apparatus is connected to the external power source and the power wiring connector of the device under test is connected to the receptacle, the current monitor circuitry is configured to detect a difference in current flowing between a hot line and a neutral line connected to the device under test of 120 volts.

15. The apparatus of claim 13, wherein while the power wiring connector of the apparatus is connected to the external power source and the power wiring connector of the device under test is connected to the receptacle, the current monitor is configured to detect a difference in current flowing between a first hot line, a second hot line, and a neutral line connected to the device under test of 240 volts.

16. The apparatus of claim 11, further comprising a user interface, a processor, and a memory having stored thereon non-transitory computer-readable instructions that, upon execution by the processor, cause the apparatus to display on the user interface at least one value associated with a digital current measurement of the differential current.

17. The apparatus of claim 16, further comprising power control circuitry comprising at least one switch configured to switch a polarity of power supplied to the device under test, wherein the instructions further cause the apparatus to display on the user interface a user interface element configured to permit user selection of the polarity of power supplied to the device under test.

18. The apparatus of claim 16, further comprising power control circuitry comprising at least one switch configured to switch to at least one of an open neutral condition or an open ground condition of power supplied to the device under test, wherein the instructions further cause the apparatus to display on the user interface a user interface element configured to permit user selection of the open neutral condition or the open ground condition of power supplied to the device under test.

19. The apparatus of claim 11, wherein the current monitor circuitry comprises at least one transformer.

20. A method for testing a device under test comprising:
connecting at least one probe to a device under test, wherein the at least one probe is electrically connected to touch probe circuitry;
detecting, via the at least one probe and using the touch probe circuitry, an analog leakage or touch current of the device under test while the device under test is connected to a power source;
converting, using analog to digital converter circuitry, the analog leakage or touch current of the device under test to at least one digital value representative of the analog leakage or touch current of the device under test; and
displaying, on a user interface, the at least one digital value representative of the analog leakage or touch current of the device under test.

21. The method of claim 16, further comprising receiving a user input, via the user interface, configured to specify a body network or frequency network for use in testing the device under test.

22. The method of claim 16, further comprising updating software instructions used for the converting of the analog leakage or touch current of the device under test to the at least one digital value.

23. A method for testing a device under test comprising:
connecting a test apparatus to a power source;
connecting a device under test to the test apparatus;
detecting, using current monitoring circuitry of the test apparatus, an analog differential current flowing through power wiring of the test apparatus that electrically connects the power source to the device under test;
converting, using analog to digital converter circuitry, the analog differential current to at least one digital value representative of the analog differential current; and
displaying, on a user interface, the at least one digital value representative of the analog leakage or touch current of the device under test.

24. The method of claim 19, further comprising updating software instructions used for the converting of the analog differential current to the at least one digital value.
